(19) United States
(12) Patent Application Publication
(10) Pub. No.: US 2021/0408352 A1
(43) Pub. Date: Dec. 30, 2021

(54) THERMOELECTRIC GENERATOR

(71) Applicant: KELK Ltd., Kanagawa (JP)

(72) Inventors: Daisuke GOTO, Kanagawa (JP); Tomonori MURATA, Kanagawa (JP)

(21) Appl. No.: 17/293,310

(22) PCT Filed: Nov. 19, 2019
(86) PCT No.: PCT/JP2019/045296

§ 371 Date: May 12, 2021

(30) Foreign Application Priority Data
Nov. 30, 2018 (JP) 2018-225061

(51) Int. Cl. H01L 35/30

(52) U.S. Cl. CPC H01L 35/30

(57) ABSTRACT

A thermoelectric generator includes a heat reception portion, a heat release portion, a thermoelectric generation module that is arranged between the heat reception portion and the heat release portion, and a heat transfer mechanism that includes a first connection portion configured to be connected to the thermoelectric generation module and a second connection portion configured to be connected to at least one of the heat reception portion and the heat release portion, the heat transfer mechanism being at least partially resiliently deformed.

### FIELD

The present invention relates to a thermoelectric generator.

### BACKGROUND

Thermoelectric generators are known that include thermoelectric generation modules generating electric power by using the Seebeck effect. Each of the thermoelectric generation modules generates electric power by a temperature difference applied between one end surface and the other end surface of the thermoelectric generation module.

### CITATION LIST

### Patent Literature

Patent Literature 1: JP 2016-157356 A

### SUMMARY

### Technical Problem

In some cases, a heat transfer member is connected to the thermoelectric generation module for heat transfer with the thermoelectric generation module. If the heat transfer member is thermally deformed, an excessive external force may be applied to the thermoelectric generation module, or the thermoelectric generation module and the heat transfer member may be separated from each other. As a result, the performance of the thermoelectric generator may deteriorate.

An object of an aspect of the present invention is to suppress a deterioration in the performance of a thermoelectric generator.

### Solution to Problem

According to an aspect of the present invention, a thermoelectric generator comprises: a heat reception portion; a heat release portion; a thermoelectric generation module that is arranged between the heat reception portion and the heat release portion; and a heat transfer mechanism that includes a first connection portion configured to be connected to the thermoelectric generation module and a second connection portion configured to be connected to at least one of the heat reception portion and the heat release portion, the heat transfer mechanism being at least partially resiliently deformed.

### Advantageous Effects of Invention

According to an aspect of the present invention, a deterioration in the performance of the thermoelectric generator is suppressed.

### BRIEF DESCRIPTION OF DRAWINGS

FIG. 1 is a cross-sectional view illustrating a thermoelectric generator according to a first embodiment.

FIG. 2 is an enlarged cross-sectional view of a portion of the thermoelectric generator according to the first embodiment.

FIG. 3 is a perspective view schematically illustrating a thermoelectric generation module according to the first embodiment.

FIG. 4 is a schematic view illustrating an example of a heat transfer mechanism according to the first embodiment.

FIG. 5 is a schematic view illustrating an example of a heat transfer mechanism according to a second embodiment.

FIG. 6 is a schematic view illustrating an example of a heat transfer mechanism according to a third embodiment.

FIG. 7 is a schematic view illustrating an example of a heat transfer mechanism according to a fourth embodiment.

FIG. 8 is a schematic view illustrating an example of a heat transfer mechanism according to a fifth embodiment.

FIG. 9 is a schematic view illustrating an example of a heat transfer mechanism according to a sixth embodiment.

### DESCRIPTION OF EMBODIMENTS

Embodiments according to the present invention will be described below with reference to the drawings, but the present invention is not limited the description. Component elements according to the embodiments described below may be appropriately combined with each other. Furthermore, some of the component elements may not be used in some cases.

In the following description, an XYZ orthogonal coordinate system is set, and positional relationships between portions will be described with reference to the XYZ orthogonal coordinate system. A direction parallel to an X-axis in a predetermined plane is represented as an X-axis direction, a direction parallel to a Y-axis orthogonal to the X-axis in the predetermined plane is represented as a Y-axis direction, and a direction parallel to a Z-axis orthogonal to the predetermined plane is represented as a Z-axis direction. An XY plane, including the X- and Y-axes, is parallel to the predetermined plane.

### First Embodiment

<Thermoelectric Generator>

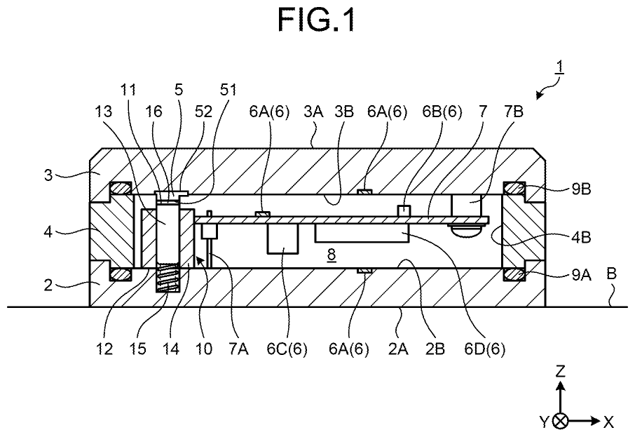

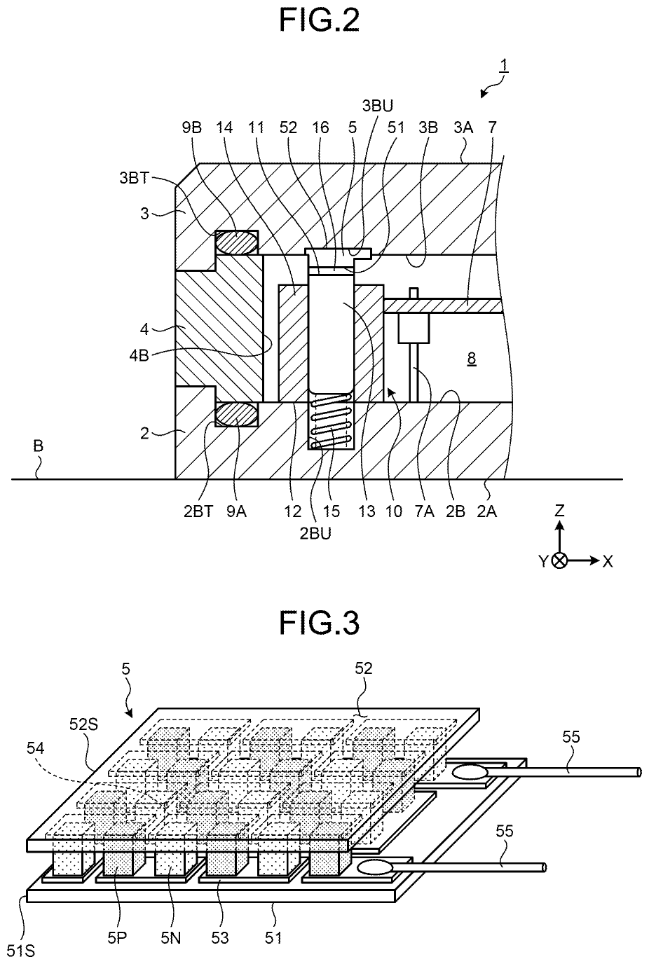

A first embodiment will be described. FIG. 1 is a cross-sectional view illustrating an example of a thermoelectric generator 1 according to the present embodiment. FIG. 2 is an enlarged cross-sectional view of a portion of the thermoelectric generator 1 according to the present embodiment. As illustrated in FIGS. 1 and 2, the thermoelectric generator 1 includes a heat reception portion 2, a heat release portion 3, a peripheral wall member 4 that is arranged between the peripheral edge portion of the heat reception portion 2 and the peripheral edge portion of the heat release portion 3, a thermoelectric generation module 5 that is arranged between the heat reception portion 2 and the heat release portion 3, a plurality of electronic components 6 configured to be driven by electric power generated by the thermoelectric generation module 5, and a substrate 7 configured to support at least some of the electronic components.

Furthermore, the thermoelectric generator 1 includes a heat transfer mechanism 10 configured to be at least partially connected to the thermoelectric generation module 5.

The heat reception portion 2 is installed on an object B. The heat reception portion 2 is a plate-shaped member. The heat reception portion 2 is made of a metal material such as aluminum or copper. The object B functions as a heat source. The heat reception portion 2 receives heat from the object B. The heat of the heat reception portion 2 is transferred to the thermoelectric generation module 5 via the heat transfer mechanism 10.

The heat release portion 3 is opposed to the heat reception portion 2 with a space therebetween. The heat release portion 3 is a plate-shaped member. The heat release portion 3 is made of a metal material such as aluminum or copper. The heat release portion 3 receives heat from the thermoelectric generation module 5. The heat of the heat release portion 3 is released into an ambient air space around the thermoelectric generator 1.

The heat reception portion 2 has a heat reception surface 2A that is opposed to a surface of the object B and an inner surface 2B that faces in a direction opposite to the heat reception surface 2A. The heat reception surface 2A faces in a −Z direction. The inner surface 2B faces in a +Z direction. Each of the heat reception surface 2A and the inner surface 2B has a flat shape. Each of the heat reception surface 2A and the inner surface 2B is parallel to the XY plane. In the XY plane, the outer shape of the heat reception portion 2 is substantially quadrangle.

The heat release portion 3 has a heat release surface 3A that faces the ambient air space and an inner surface 3B that faces in a direction opposite to the heat release surface 3A. The heat release surface 3A faces in the +Z direction. The inner surface 3B faces in the −Z direction. Each of the heat release surface 3A and the inner surface 3B has a flat shape. Each of the heat release surface 3A and the inner surface 3B is parallel to the XY plane. In the XY plane, the outer shape of the heat release portion 3 is substantially quadrangle.

In the XY plane, the outer shape and dimensions of the heat reception portion 2 and the outer shape and dimensions of the heat release portion 3 are substantially equivalent.

The peripheral wall member 4 is arranged between the peripheral edge portion of the inner surface 2B of the heat reception portion 2 and the peripheral edge portion of the inner surface 3B of the heat release portion 3. The peripheral wall member 4 connects the heat reception portion 2 and the heat release portion 3. The peripheral wall member 4 is made of a synthetic resin.

In the XY plane, the peripheral wall member 4 has an annular shape. In the XY plane, the outer shape of the peripheral wall member 4 is substantially quadrangle. The heat reception portion 2, the heat release portion 3, and the peripheral wall member 4 define an inner space 8 of the thermoelectric generator 1. The peripheral wall member 4 has an inner surface 4B that faces the inner space 8. The inner surface 2B of the heat reception portion 2 faces the inner space 8. The inner surface 3B of the heat release portion 3 faces the inner space 8. The ambient air space around the thermoelectric generator 1 is an outer space of the thermoelectric generator 1.

A sealing member 9A is arranged between the peripheral edge portion of the inner surface 2B of the heat reception portion 2 and an end surface on the −Z side of the peripheral wall member 4. A sealing member 9B is arranged between the peripheral edge portion of the inner surface 3B of the heat release portion 3 and an end surface on the +Z side of the peripheral wall member 4. Each of the sealing member 9A and the sealing member 9B includes, for example, an O-ring. The sealing member 9A is arranged in a recess 2BT provided at the peripheral edge portion of the inner surface 2B. The sealing member 9B is arranged in a recess 3BT provided at the peripheral edge portion of the inner surface 3B. The sealing member 9A and the sealing member 9B prevent entrance of foreign matter in the outer space of the thermoelectric generator 1 into the inner space 8.

The thermoelectric generation module 5 uses the Seebeck effect to generate electric power. An end surface 51 on the −Z side of the thermoelectric generation module 5 is heated to apply a temperature difference between the end surface 51 on the −Z side and an end surface 52 on the +Z side of the thermoelectric generation module 5, and thereby the thermoelectric generation module 5 generates electric power.

The end surface 51 faces in the −Z direction. The end surface 52 faces in the +Z direction. Each of the end surface 51 and the end surface 52 has a flat shape. Each of the end surface 51 and the end surface 52 is parallel to the XY plane. In the XY plane, the outer shape of the thermoelectric generation module 5 is substantially quadrangle.

The end surface 52 is opposed to the inner surface 3B of the heat release portion 3. A recess 3BU is formed in the inner surface 3B of the heat release portion 3. At least part of the thermoelectric generation module 5 is arranged in the recess 3BU. The thermoelectric generation module 5 is fixed to the heat release portion 3. The heat release portion 3 and the thermoelectric generation module 5 are bonded to each other, for example, by an adhesive.

FIG. 3 is a perspective view schematically illustrating the thermoelectric generation module 5 according to the present embodiment. The thermoelectric generation module 5 includes p-type thermoelectric semiconductor devices 5P, n-type thermoelectric semiconductor devices 5N, first electrodes 53, second electrodes 54, a first substrate 51S, and a second substrate 52S. In the XY plane, the p-type thermoelectric semiconductor devices 5P and the n-type thermoelectric semiconductor devices 5N are arranged alternately. Each of the first electrodes 53 is connected to each of the p-type thermoelectric semiconductor devices 5P and n-type thermoelectric semiconductor devices 5N. Each of the second electrodes 54 is connected to each of the p-type thermoelectric semiconductor devices 5P and n-type thermoelectric semiconductor devices 5N. A lower surface of the p-type thermoelectric semiconductor device 5P and a lower surface of the n-type thermoelectric semiconductor device 5N are connected to the first electrode 53. An upper surface of the p-type thermoelectric semiconductor device 5P and an upper surface of the n-type thermoelectric semiconductor device 5N are connected to the second electrode 54. The first electrode 53 is connected to the first substrate 51S. The second electrode 54 is connected to the second substrate 52S.

Each of the p-type thermoelectric semiconductor device 5P and n-type thermoelectric semiconductor device 5N includes, for example, a BiTe-based thermoelectric material. Each of the first substrate 51S and second substrate 52S is made of an electrical insulating material such as ceramics or polyimide.

The first substrate 51S has the end surface 51. The second substrate 52S has the end surface 52. In response to heating the first substrate 51S, a temperature difference is applied between end portions on the +Z-side and −Z side of each p-type thermoelectric semiconductor device 5P and n-type thermoelectric semiconductor device 5N. In response to applying the temperature difference between the end portions on the +Z side and −Z side of the p-type thermoelectric semiconductor device 5P, holes move in the p-type thermoelectric semiconductor device 5P. In response to applying the temperature difference between the end portions on the +Z side and −Z side of the n-type thermoelectric semiconductor device 5N, electrons move in the n-type thermoelectric semiconductor device 5N. The p-type thermoelectric semiconductor device 5P and the n-type thermoelectric semiconductor device 5N are connected via the first electrode 53 and the second electrode 54. A potential difference is generated between the first electrode 53 and the second electrode 54 due to holes and electrons. The thermoelectric generation module 5 generates electric power due to the potential difference between the first electrode 53 and the second electrode 54. A lead wire 55 is connected to a first electrode 53. The thermoelectric generation module 5 outputs electric power via the lead wire 55.

The electronic components 6 are each driven by electric power generated by the thermoelectric generation module 5. The thermoelectric generator 1 includes the plurality of electronic components 6. At least some of the electronic components 6 are arranged in the inner space 8.

In the present embodiment, the electronic components 6 include a sensor 6A and a transmitter 6B that is configured to transmit detection data from the sensor 6A. Furthermore, the electronic components 6 include an amplifier 6C configured to amplify the detection data from the sensor 6A, and a microcomputer 6D configured to control each of the sensor 6A, transmitter 6B, and amplifier 6C.

The substrate 7 includes a control board configured to support at least some of the electronic components 6. The substrate 7 is arranged in the inner space 8. The substrate 7 is connected to the heat reception portion 2 via a support member 7A. The substrate 7 is connected to the heat release portion 3 via a support member 7B. The substrate 7 is supported by the support member 7A and the support member 7B so as to be separated from each of the heat reception portion 2 and the heat release portion 3.

The sensor 6A includes, for example, a temperature sensor. In the present embodiment, three sensors 6A are arranged. The sensors 6A are each arranged at the heat reception portion 2, the heat release portion 3, and the substrate 7. The detection data from each of the sensors 6A is amplified by the amplifier 6C and then transmitted by the transmitter 6B to a management device located outside the thermoelectric generator 1.

<Heat Transfer Mechanism>

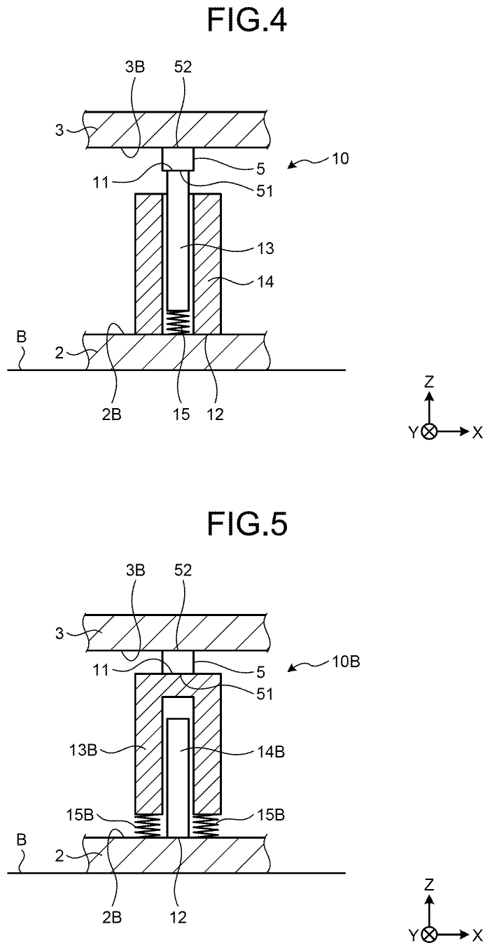

FIG. 4 is a schematic view illustrating an example of the heat transfer mechanism 10 according to the present embodiment. The heat transfer mechanism 10 receives heat from the heat reception portion 2 and transfers the heat to the thermoelectric generation module 5.

As illustrated in FIGS. 1, 2, and 4, the heat transfer mechanism 10 includes a first connection portion 11 configured to be connected to the thermoelectric generation module 5 and a second connection portion 12 configured to be connected to the heat reception portion 2. At least part of the heat transfer mechanism 10 is resiliently deformed. At least part of the heat transfer mechanism 10 is arranged in the inner space 8.

In the present embodiment, the heat transfer mechanism 10 includes a first heat transfer member 13 that includes the first connection portion 11, a resilient portion 15 that is arranged between the first heat transfer member 13 and the heat reception portion 2, and a second heat transfer member 14 that includes the second connection portion 12 and is configured to guide the first heat transfer member 13.

The first heat transfer member 13 is made of a metal material such as aluminum or copper. The first heat transfer member 13 is a rod-shaped member elongated in a Z-axis direction. In the present embodiment, the first heat transfer member 13 is a columnar member.

The first connection portion 11 includes an end portion on the +Z side of the first heat transfer member 13. The first heat transfer member 13 is connected to the end surface 51 of the thermoelectric generation module 5. In the present embodiment, the first connection portion 11 is connected to the end surface 51 of the thermoelectric generation module 5 via a heat transfer sheet 16. The heat transfer sheet 16 is flexible. The heat transfer sheet 16 is made of, for example, carbon. In FIG. 4, illustration of the heat transfer sheet 16 is omitted.

The second heat transfer member 14 is made of a metal material such as aluminum or copper. The second heat transfer member 14 is a cylindrical member that is arranged around the first heat transfer member 13. In the present embodiment, the second heat transfer member 14 is a cylindrical member.

The second connection portion 12 includes an end portion on the −Z side of the second heat transfer member 14. The second heat transfer member 14 is fixed to the heat reception portion 2. The first heat transfer member 13 is movable in a Z-axis direction. The second heat transfer member 14 guides the first heat transfer member 13 in the Z-axis direction.

The resilient portion 15 resiliently deforms in a Z-axis direction. In the present embodiment, the resilient portion 15 includes a resilient member such as a coil spring. The resilient portion 15 is arranged between an end portion on the −Z side of the first heat transfer member 13 and the inner surface 2B of the heat reception portion 2. An end portion on the +Z side of the resilient portion 15 is connected to the end portion on the −Z side of the first heat transfer member 13. As illustrated in FIGS. 1 and 2, a recess 2BU is formed in the inner surface 2B of the heat reception portion 2. At least part of the resilient portion 15 is arranged in the recess 2BU. An end portion on the −Z side of the resilient portion 15 is connected to a bottom surface of the recess 2BU.

The resilient portion 15 is compressed and arranged between the first heat transfer member 13 and the heat reception portion 2. The resilient portion 15 is arranged between the first heat transfer member 13 and the heat reception portion 2 and generates a resilient force that moves the first heat transfer member 13 in the +Z direction.

When the first heat transfer member 13 is thermally deformed in a Z-axis direction, the resilient portion 15 extends and contracts in the Z-axis direction. For example, when the first heat transfer member 13 is thermally deformed so as to extend in a Z-axis direction, the resilient portion 15 contracts in the Z-axis direction. When the first heat transfer member 13 is thermally deformed so as to contract in a Z-axis direction, the resilient portion 15 extends in the Z-axis direction. The second heat transfer member 14 guides the first heat transfer member 13 that is thermally deformed in the Z-axis direction.

The first heat transfer member 13 and at least part of the second heat transfer member 14 make contact with each other. In the present embodiment, the outer peripheral surface of the first heat transfer member 13 and at least part of the inner peripheral surface of 14 make contact with each other. The first heat transfer member 13 moves in a Z-axis direction while making contact with the inner peripheral surface of the second heat transfer member 14. The contact between the outer peripheral surface of the first heat transfer member 13 and the inner peripheral surface of the second heat transfer member 14 enables sufficient heat transfer between the first heat transfer member 13 and the second heat transfer member 14. In addition, a lubricant having a heat transfer characteristic such as heat conductive grease may be provided between the outer peripheral surface of the first heat transfer member 13 and the inner peripheral surface of the second heat transfer member 14.

<Operation>

Next, an example of the operation of the thermoelectric generator 1 according to the present embodiment will be described. The thermoelectric generator 1 is installed on the object B provided in an industrial facility such as a factory. The object B includes a device or machine installed in the industrial facility. In a case where the sensor 6A of the thermoelectric generator 1 is a temperature sensor, the thermoelectric generator 1 detects the temperature of the object B by using the sensor 6A.

The object B generates heat. The heat of the object B is transferred to the thermoelectric generation module 5 via the heat reception portion 2 and the heat transfer mechanism 10. The second connection portion 12 of the second heat transfer member 14 makes contact with the heat reception portion 2. The second heat transfer member 14 and the first heat transfer member 13 make contact with each other. The first connection portion 11 of the first heat transfer member 13 makes contact with the thermoelectric generation module 5. Therefore, sufficient heat of the object B is transferred to the thermoelectric generation module 5 via the heat reception portion 2, the first heat transfer member 13, and the second heat transfer member 14.

The thermoelectric generation module 5 that has received heat generates electric power. The electronic components 6 are each driven by electric power generated by the thermoelectric generation module 5. As described above, in the present embodiment, the electronic components 6 include the sensor 6A, the transmitter 6B, the amplifier 6C, and the microcomputer 6D. The sensor 6A detects the temperature of the object B. The microcomputer 6D amplifies detection data from the sensor 6A by the amplifier 6C, and then transmits the detection data to the management device in the industrial facility located outside the thermoelectric generator 1 via the transmitter 6B. The thermoelectric generator 1 is installed on each of a plurality of the objects B in the industrial facility. The management device is configured to monitor and manage the states of the plurality of the B, on the basis of the detection data transmitted from the plurality of the thermoelectric generators 1.

The heat from the object B is likely to thermally deform at least part of the heat transfer mechanism 10 in a Z-axis direction. For example, if the first heat transfer member 13 is thermally deformed in a Z-axis direction, an excessive external force may be applied to the thermoelectric generation module 5 or the thermoelectric generation module 5 may be separated from the first heat transfer member 13. If the first heat transfer member 13 is thermally deformed so as to extend in a Z-axis direction, the thermoelectric generation module 5 may be crushed between the first heat transfer member 13 and the heat release portion 3, applying an excessive external force to the thermoelectric generation module 5. If the first heat transfer member 13 is thermally deformed so as to contract in a Z-axis direction, the thermoelectric generation module 5 may be separated from the first heat transfer member 13, transferring insufficient heat between the thermoelectric generation module 5 and the heat reception portion 2.

In the present embodiment, at least part of the heat transfer mechanism 10 is resiliently deformed so as to maintain the distance between the first connection portion 11 and the inner surface 3B of the heat release portion 3 in a Z-axis direction. Thus, this configuration suppresses that an excessive external force is applied to the thermoelectric generation module 5 and that the thermoelectric generation module 5 is separated from the heat transfer mechanism 10.

When the first heat transfer member 13 is thermally deformed so as to extend in a Z-axis direction, the resilient portion 15 is resiliently deformed so as to contract in the Z-axis direction. The second heat transfer member 14 guides the first heat transfer member 13 that is thermally deformed so as to extend in the Z-axis direction. When the resilient portion 15 is resiliently deformed so as to contract in the Z-axis direction, the position of the end portion on the −Z side of the first heat transfer member 13 in the Z-axis direction is changed, but a change in distance in the Z-axis direction between the inner surface 3B of the heat release portion 3 and the first connection portion 11 that is the end portion on the +Z side of the first heat transfer member 13 is suppressed.

When the first heat transfer member 13 is thermally deformed so as to contract in the Z-axis direction, the resilient portion 15 is resiliently deformed so as to extend in the Z-axis direction. The resilient portion 15 is compressed and arranged between the first heat transfer member 13 and the heat reception portion 2. Thus, thermal deformation of the first heat transfer member 13 so as to contract in the Z-axis direction enables the resilient portion 15 to thermally deform so as to extend in the Z-axis direction. The second heat transfer member 14 guides the first heat transfer member 13 that is thermally deformed so as to contract in the Z-axis direction. When the resilient portion 15 is resiliently deformed so as to extend in the Z-axis direction, the position of the end portion on the −Z side of the first heat transfer member 13 in the Z-axis direction is changed, but a change in distance in the Z-axis direction between the inner surface 3B of the heat release portion 3 and the first connection portion 11 that is the end portion on the +Z side of the first heat transfer member 13 is suppressed.

In this way, the resilient portion 15 that is resiliently deformable in a Z-axis direction is provided, and thereby, even if the first heat transfer member 13 is thermally deformed in a Z-axis direction, a change in distance between the inner surface 3B of the heat release portion 3 and the first connection portion 11 of the first heat transfer member 13 in the Z-axis direction is suppressed. Thus, an excessive external force applied to the thermoelectric generation module 5 or separation of the end surface 51 of the thermoelectric generation module 5 from the first connection portion 11 of the first heat transfer member 13 is suppressed.

<Effects>

As described above, according to the present embodiment, the heat transfer mechanism 10 is provided that includes the first connection portion 11 configured to be connected to the thermoelectric generation module 5 and the second connection portion 12 configured to be connected to the heat reception portion 2. This configuration sufficiently transfers the heat of the heat reception portion 2 to the thermoelectric generation module 5 via the heat transfer mechanism 10. Therefore, a sufficient temperature difference is applied between the end surface 51 and end surface 52 of the thermoelectric generation module 5. Thus the thermoelectric generator 1 is configured to generate sufficient electric power.

In a case where the first heat transfer member 13 is connected to the thermoelectric generation module 5 to transfer heat to the thermoelectric generation module 5, the first heat transfer member 13 is likely to be thermally deformed. In the present embodiment, the heat transfer mechanism 10 has the resilient portion 15 that is resiliently deformable. Therefore, even if the first heat transfer member 13 is thermally deformed, the resilient portion 15 is resiliently deformed, suppressing an excessive external force applied to the thermoelectric generation module 5 or separation of the thermoelectric generation module 5 from the first heat transfer member 13. Therefore, a deterioration in the performance of the thermoelectric generator 1 is suppressed.

The peripheral wall member 4 is made of a synthetic resin. The peripheral wall member 4 has a heat insulating property. Therefore, the transfer of heat of the heat reception portion 2 to the heat release portion 3 via the peripheral wall member 4 is suppressed. The heat of the heat reception portion 2 is transferred to the thermoelectric generation module 5 exclusively via the heat transfer mechanism 10 provided in the inner space 8. This configuration suppresses the loss of heat transferred from the heat reception portion 2 to the thermoelectric generation module 5.

The first heat transfer member 13 is made of a metal such as aluminum or copper, and the peripheral wall member 4 is made of a synthetic resin. The coefficient of thermal expansion of the peripheral wall member 4 is larger than the coefficient of thermal expansion of the first heat transfer member 13. Therefore, thermal deformation of the peripheral wall member 4 in a Z-axis direction may change the distance between the heat reception portion 2 and the heat release portion 3 in the Z-axis direction. In the present embodiment, the first heat transfer member 13 is supported by the resilient portion 15, and thereby, even if the distance from the heat reception portion 2 to the heat release portion 3 in a Z-axis direction changes, a change in distance between the inner surface 3B of the heat release portion 3 and the first connection portion 11 of the first heat transfer member 13 in the Z-axis direction is suppressed. Therefore, an excessive external force applied to the thermoelectric generation module 5, which is arranged between the heat release portion 3 and the first heat transfer member 13, or separation of the thermoelectric generation module 5 from the first heat transfer member 13 is suppressed.

The first heat transfer member 13 is guided by the second heat transfer member 14. The second heat transfer member 14 guides the first heat transfer member 13 in an exclusive direction in which the first heat transfer member 13 is thermally deformed. In the present embodiment, the direction in which the first heat transfer member 13 is thermally deformed is a Z-axis direction. The direction of guiding by the second heat transfer member 14 is the Z-axis direction. Therefore, the first heat transfer member 13 is configured to smoothly move in the Z-axis direction.

The first heat transfer member 13 and at least part of the second heat transfer member 14 make contact with each other. Therefore, sufficient heat of the object B is transferred to the thermoelectric generation module 5 via the heat reception portion 2, the first heat transfer member 13, and the second heat transfer member 14.

The first connection portion 11 is connected to the thermoelectric generation module 5 via the heat transfer sheet 16 having flexibility. With this configuration, even if, for example, the first heat transfer member 13 is thermally deformed in a direction inclined relative to the Z-axis, the heat transfer sheet 16 suppresses the application of a local external force to the thermoelectric generation module 5.

At least part of the heat transfer mechanism 10 is arranged in the inner space 8 defined by the heat reception portion 2, heat release portion 3, and peripheral wall member 4. Therefore, the heat transfer mechanism 10 is protected by the heat reception portion 2, heat release portion 3, and peripheral wall member 4. The heat transfer mechanism 10 arranged in the inner space 8 suppresses attachment of foreign matter to the heat transfer mechanism 10. Therefore, the first heat transfer member 13 and the second heat transfer member 14 are smoothly movable relative to each other.

At least some of the electronic components 6 are arranged in the inner space 8 defined by the heat reception portion 2, heat release portion 3, and peripheral wall member 4. Therefore, the electronic components 6 are protected by the heat reception portion 2, heat release portion 3, and peripheral wall member 4. The arrangement of the electronic components 6 in the inner space 8 suppresses attachment of foreign matter to the electronic components 6.

The electronic components 6 include the sensor 6A and the transmitter 6B that is configured to transmit detection data from the sensor 6A. This configuration makes it possible for the management device located outside the thermoelectric generator 1 to smoothly acquire the detection data from the sensor 6A. In a case where the thermoelectric generator 1 is installed on each of the plurality of objects B in the industrial facility, the management device is configured to monitor and manage the states of the plurality of the B, on the basis of the detection data from the sensors 6A transmitted from the plurality of the thermoelectric generators 1.

### Second Embodiment

A second embodiment will be described. In the following description, component elements that are the same as or equivalent to those in the above embodiment are denoted by the same reference numerals, and description thereof will be simplified or omitted.

FIG. 5 is a schematic view illustrating an example of a heat transfer mechanism 10B according to the present embodiment. As illustrated in FIG. 5, the heat transfer mechanism 10B includes a first heat transfer member 13B that includes the first connection portion 11 configured to be connected to the thermoelectric generation module 5, a resilient portion 15B that is arranged between the first heat transfer member 13B and the heat reception portion 2, and a second heat transfer member 14B that includes the second connection portion 12 configured to be connected to the heat reception portion 2 and is configured to guide the first heat transfer member 13B.

The first heat transfer member 13B is a cylindrical member that has a top plate portion. The first connection portion 11 includes an end portion on the +Z side of the first heat transfer member 13B. The first heat transfer member 13B is connected to the end surface 51 of the thermoelectric generation module 5.

The second heat transfer member 14B is a rod-shaped member that is arranged inside the first heat transfer member 13B. The second connection portion 12 includes an end portion on the −Z side of the second heat transfer member 14B. The second heat transfer member 14B is fixed to the heat reception portion 2. The first heat transfer member 13B and the second heat transfer member 14B are movable relative to each other in a Z-axis direction. The second heat transfer member 14B guides the first heat transfer member 13B in a Z-axis direction.

The resilient portion 15B resiliently deforms in a Z-axis direction. The resilient portion 15B includes a resilient member such as a coil spring. The resilient portion 15B is arranged between an end portion on the −Z side of the first heat transfer member 13B and the inner surface 2B of the heat reception portion 2. An end portion on the +Z side of the resilient portion 15B is connected to the end portion on the −Z side of the first heat transfer member 13B.

As described above, also in the present embodiment, an excessive external force applied to the thermoelectric generation module 5 or separation of the thermoelectric generation module 5 from the first heat transfer member 13B is suppressed. Accordingly, a deterioration in the performance of the thermoelectric generator 1 is suppressed.

### Third Embodiment

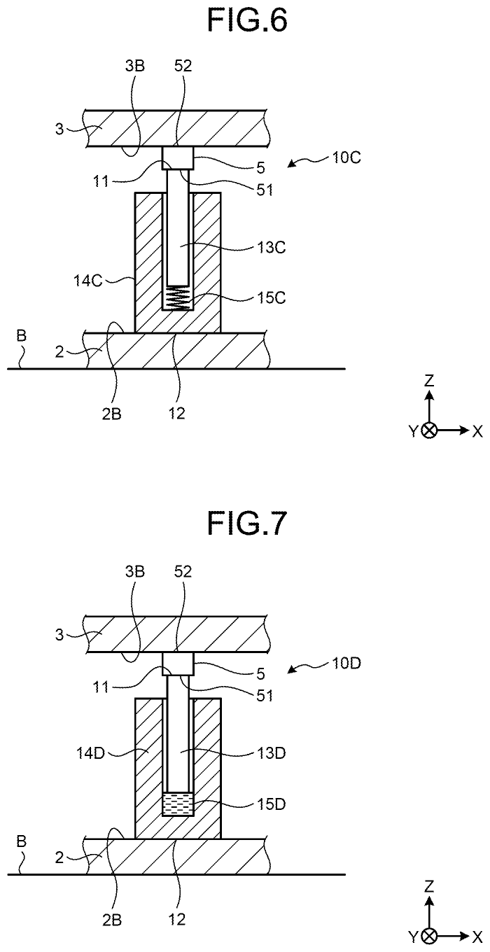

A third embodiment will be described. FIG. 6 is a schematic view illustrating an example of a heat transfer mechanism 10C according to the present embodiment. As illustrated in FIG. 6, the heat transfer mechanism 10C includes a first heat transfer member 13C that includes the first connection portion 11, a second heat transfer member 14C that includes the second connection portion 12 and is configured to guide the first heat transfer member 13C, and a resilient portion 15C that is arranged between the first heat transfer member 13C and the second heat transfer member 14C.

The first heat transfer member 13C is a rod-shaped member. The first connection portion 11 includes an end portion on the +Z side of the first heat transfer member 13C. The first heat transfer member 13C is connected to the end surface 51 of the thermoelectric generation module 5.

The second heat transfer member 14C is a cylindrical member that has a bottom plate portion. The second connection portion 12 includes an end portion on the −Z side of the second heat transfer member 14C. The second heat transfer member 14C is fixed to the heat reception portion 2. The first heat transfer member 13C and the second heat transfer member 14C are movable relative to each other in a Z-axis direction. The second heat transfer member 14C guides the first heat transfer member 13C in a Z-axis direction.

The resilient portion 15C resiliently deforms in a Z-axis direction. The resilient portion 15C includes a resilient member such as a coil spring. The resilient portion 15C is arranged between an end portion on the −Z side of the first heat transfer member 13C and the bottom plate portion of the second heat transfer member 14C. An end portion on the +Z side of the resilient portion 15B is connected to the end portion on the −Z side of the first heat transfer member 13C.

As described above, also in the present embodiment, an excessive external force applied to the thermoelectric generation module 5 or separation of the thermoelectric generation module 5 from the first heat transfer member 13C is suppressed. Accordingly, a deterioration in the performance of the thermoelectric generator 1 is suppressed.

### Fourth Embodiment

A fourth embodiment will be described. FIG. 7 is a schematic view illustrating an example of a heat transfer mechanism 10D according to the present embodiment. As illustrated in FIG. 7, the heat transfer mechanism 10D includes a first heat transfer member 13D that includes the first connection portion 11, a second heat transfer member 14D that includes the second connection portion 12 and is configured to guide the first heat transfer member 13D, and a resilient portion 15D that is arranged between the first heat transfer member 13D and the second heat transfer member 14D.

The first heat transfer member 13D is a rod-shaped member. The first connection portion 11 includes an end portion on the +Z side of the first heat transfer member 13D. The first heat transfer member 13D is connected to the end surface 51 of the thermoelectric generation module 5.

The second heat transfer member 14D is a cylindrical member that has a bottom plate portion. The second connection portion 12 includes an end portion on the −Z side of the second heat transfer member 14D. The second heat transfer member 14D is fixed to the heat reception portion 2. The first heat transfer member 13D and the second heat transfer member 14D are movable relative to each other in a Z-axis direction. The second heat transfer member 14D guides the first heat transfer member 13D in a Z-axis direction.

The resilient portion 15D resiliently deforms in a Z-axis direction. The resilient portion 15D contains a compressible fluid such as a gas. The resilient portion 15D is arranged between an end portion on the −Z side of the first heat transfer member 13D and the bottom plate portion of the second heat transfer member 14D.

As described above, also in the present embodiment, an excessive external force applied to the thermoelectric generation module 5 or separation of the thermoelectric generation module 5 from the first heat transfer member 13D is suppressed. Accordingly, a deterioration in the performance of the thermoelectric generator 1 is suppressed.

### Fifth Embodiment

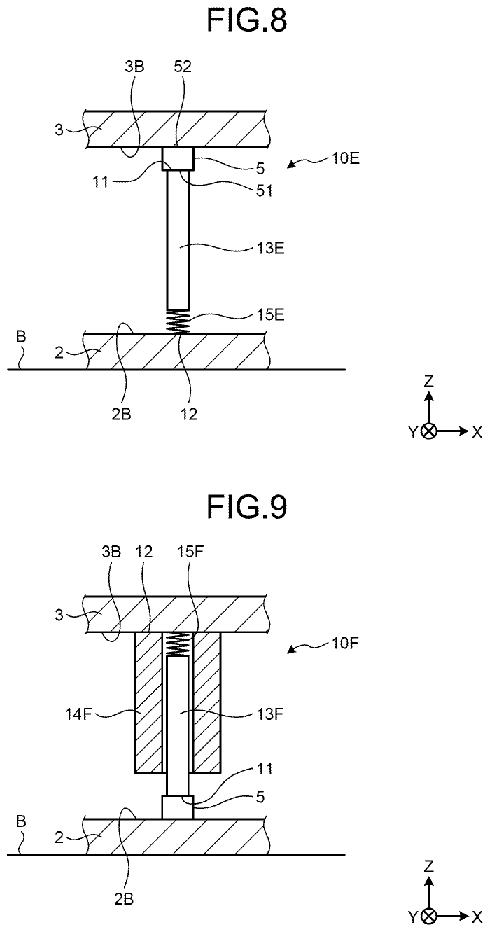

A fifth embodiment will be described. FIG. 8 is a schematic view illustrating an example of a heat transfer mechanism 10E according to the present embodiment. As illustrated in FIG. 8, the heat transfer mechanism 10E includes a first heat transfer member 13E that includes the first connection portion 11 and a resilient portion 15E that includes the second connection portion 12 and is arranged between the first heat transfer member 13E and the heat reception portion 2.

The first heat transfer member 13E is a rod-shaped member. The first connection portion 11 includes an end portion on the +Z side of the first heat transfer member 13E. The first heat transfer member 13E is connected to the end surface 51 of the thermoelectric generation module 5.

The resilient portion 15E resiliently deforms in a Z-axis direction. The second connection portion 12 includes an end portion on the −Z side of the resilient portion 15E. The end portion on the −Z side of the resilient portion 15E is fixed to the heat reception portion 2. The resilient portion 15E is arranged between an end portion on the −Z side of the first heat transfer member 13E and the heat reception portion 2. The first heat transfer member 13E is supported by the resilient portion 15E.

As described above, also in the present embodiment, an excessive external force applied to the thermoelectric generation module 5 or separation of the thermoelectric generation module 5 from the first heat transfer member 13D is suppressed. Accordingly, a deterioration in the performance of the thermoelectric generator 1 is suppressed.

Note that in the present embodiment, the resilient portion 15E may be arranged between the first heat transfer member 13E and the heat release portion 3, and the thermoelectric generation module 5 may be arranged between the first heat transfer member 13E and the heat reception portion 2. In this configuration, the resilient portion 15E includes the first connection portion 11 configured to be connected to the heat release portion 3, and the first heat transfer member 13E includes the second connection portion 12 configured to be connected to the heat reception portion 2.

### Sixth Embodiment

A sixth embodiment will be described. FIG. 9 is a schematic view illustrating an example of a heat transfer mechanism 10F according to the present embodiment. As illustrated in FIG. 6, the heat transfer mechanism 10F includes a first heat transfer member 13F that includes the first connection portion 11 configured to be connected to the thermoelectric generation module 5, a resilient portion 15F that is arranged between the first heat transfer member 13F and the heat release portion 3, and a second heat transfer member 14F that includes the second connection portion 12 configured to be connected to the heat release portion 3 and is configured to guide the first heat transfer member 13F.

The first heat transfer member 13F is a rod-shaped member. The first connection portion 11 includes an end portion on the −Z side of the first heat transfer member 13F. The thermoelectric generation module 5 is arranged between the first connection portion 11 of the first heat transfer member 13F and the heat reception portion 2.

The second heat transfer member 14F is a cylindrical member that is arranged around the first heat transfer member 13F. The second connection portion 12 includes an end portion on the +Z side of the second heat transfer member 14F. The second heat transfer member 14F is fixed to the heat release portion 3. The first heat transfer member 13F and the second heat transfer member 14F are movable relative to each other in a Z-axis direction. The second heat transfer member 14F guides the first heat transfer member 13F in a Z-axis direction.

The resilient portion 15F resiliently deforms in a Z-axis direction. The resilient portion 15F includes a resilient member such as a coil spring. The resilient portion 15F is arranged between an end portion on the +Z side of the first heat transfer member 13F and the heat release portion 3. An end portion on the +Z side of the resilient portion 15F is connected to the heat release portion 3. An end portion on the −Z side of the resilient portion 5F is fixed to the first heat transfer member 13F.

As described above, also in the present embodiment, an excessive external force applied to the thermoelectric generation module 5 or separation of the thermoelectric generation module 5 from the first heat transfer member 13F is suppressed. Accordingly, a deterioration in the performance of the thermoelectric generator 1 is suppressed.

### Other Embodiments

In the embodiments described above, the resilient portions 15 (15B, 15C, 15E, 15F) may not have the coil spring. The resilient portion 15 may have at least one of a leaf spring, disc spring, resin spring, and spiral spring.

In the embodiments described above, a resilient portion 15 (15D) does not need to be a compressible gas but may be a liquid.

In the embodiments described above, the resilient portion 15 (15B, 15C, 15D, 15E, 15F) may not be a spring and may be an elastic member such as rubber.

In the embodiments described above, the heat transfer sheet 16 may be omitted.

In the embodiments described above, the sensor 6A is not limited to the temperature sensor. The sensor 6A may be, for example, a vibration sensor.

### REFERENCE SIGNS LIST

1 THERMOELECTRIC GENERATOR
2 HEAT RECEPTION PORTION
2A HEAT RECEPTION SURFACE
2B INNER SURFACE
2BT RECESS
2BU RECESS
3 HEAT RELEASE PORTION
3A HEAT RELEASE SURFACE
3B INNER SURFACE
3BT RECESS
3BU RECESS
4 PERIPHERAL WALL MEMBER
4B INNER SURFACE
5 THERMOELECTRIC GENERATION MODULE
5P p-TYPE THERMOELECTRIC SEMICONDUCTOR DEVICE
5N n-TYPE THERMOELECTRIC SEMICONDUCTOR DEVICE
6 ELECTRONIC COMPONENT
6A SENSOR
6B TRANSMITTER
6C AMPLIFIER
6D MICROCOMPUTER
7 SUBSTRATE
7A SUPPORT MEMBER
7B SUPPORT MEMBER
8 INNER SPACE
9A SEALING MEMBER
9B SEALING MEMBER
10 HEAT TRANSFER MECHANISM
10B HEAT TRANSFER MECHANISM
10C HEAT TRANSFER MECHANISM
10D HEAT TRANSFER MECHANISM
10E HEAT TRANSFER MECHANISM
10F HEAT TRANSFER MECHANISM
11 FIRST CONNECTION PORTION
12 SECOND CONNECTION PORTION
13 FIRST HEAT TRANSFER MEMBER
13B FIRST HEAT TRANSFER MEMBER
13C FIRST HEAT TRANSFER MEMBER
13D FIRST HEAT TRANSFER MEMBER
13E FIRST HEAT TRANSFER MEMBER
13F FIRST HEAT TRANSFER MEMBER
14 SECOND HEAT TRANSFER MEMBER
14B SECOND HEAT TRANSFER MEMBER
14C SECOND HEAT TRANSFER MEMBER
14D SECOND HEAT TRANSFER MEMBER
14F SECOND HEAT TRANSFER MEMBER
15 RESILIENT PORTION
15B RESILIENT PORTION
15C RESILIENT PORTION
15D RESILIENT PORTION
15E RESILIENT PORTION
15F RESILIENT PORTION
16 HEAT TRANSFER SHEET
51 END SURFACE
51S FIRST SUBSTRATE
52 END SURFACE
52S SECOND SUBSTRATE
53 FIRST ELECTRODE
54 SECOND ELECTRODE
55 LEAD WIRE
B OBJECT

1. A thermoelectric generator comprising:
a heat reception portion;
a heat release portion;
a thermoelectric generation module that is arranged between the heat reception portion and the heat release portion; and
a heat transfer mechanism that includes a first connection portion configured to be connected to the thermoelectric generation module and a second connection portion configured to be connected to at least one of the heat reception portion and the heat release portion, the heat transfer mechanism being at least partially resiliently deformed.

2. The thermoelectric generator according to claim 1, wherein the heat transfer mechanism includes:
a first heat transfer member that includes the first connection portion; and
a resilient portion that includes the second connection portion and is arranged between the first heat transfer member and at least one of the heat reception portion and the heat release portion.

3. The thermoelectric generator according to claim 1, wherein the heat transfer mechanism includes:
a first heat transfer member that includes the first connection portion;
a resilient portion that is arranged between the first heat transfer member and at least one of the heat reception portion and the heat release portion; and
a second heat transfer member that includes the second connection portion and is configured to guide the first heat transfer member.

4. The thermoelectric generator according to claim 3, wherein the first heat transfer member is a rod-shaped member, and
the second heat transfer member is a cylindrical member that is arranged around the first heat transfer member.

5. The thermoelectric generator according to claim 3, wherein the first heat transfer member is a cylindrical member, and
the second heat transfer member is a rod-shaped member that is arranged inside the first heat transfer member.

6. The thermoelectric generator according to claim 1, wherein the heat transfer mechanism includes:
a first heat transfer member that includes the first connection portion;
a second heat transfer member that includes the second connection portion and is configured to guide the first heat transfer member; and
a resilient portion that is arranged between the first heat transfer member and the second heat transfer member.

7. The thermoelectric generator according to claim 3, wherein the first heat transfer member and at least part of the second heat transfer member make contact with each other.

8. The thermoelectric generator according to claim 2, wherein the first connection portion is connected to the thermoelectric generation module via a heat transfer sheet.

9. The thermoelectric generator according to claim 1, further comprising:
a peripheral wall member that is arranged between a peripheral edge portion of the heat reception portion and a peripheral edge portion of the heat release portion and is configured to connect the heat reception portion and the heat release portion,
wherein at least part of the heat transfer mechanism is arranged in an inner space defined by the heat reception portion, the heat release portion, and the peripheral wall member.

10. The thermoelectric generator according to claim 9, further comprising electronic components that are driven by electric power generated by the thermoelectric generation module,
wherein at least some of the electronic components are arranged in the inner space.

11. The thermoelectric generator according to claim 10, wherein the electronic components include a sensor and a transmitter that is configured to transmit detection data from the sensor.

12. The thermoelectric generator according to claim 6, wherein the first heat transfer member and at least part of the second heat transfer member make contact with each other.

13. The thermoelectric generator according to claim 3, wherein the first connection portion is connected to the thermoelectric generation module via a heat transfer sheet.

14. The thermoelectric generator according to claim 6, wherein the first connection portion is connected to the thermoelectric generation module via a heat transfer sheet.
